(19) United States
(12) Patent Application Publication
(10) Pub. No.: US 2014/0152157 A1
(43) Pub. Date: Jun. 5, 2014

(54) ELECTRONIC DEVICE ENCLOSURE

(71) Applicants: HON HAI PRECISION INDUSTRY CO., LTD., New Taipei (TW); HONG FU JIN PRECISION INDUSTRY (ShenZhen) CO., LTD., Shenzhen (CN)

(72) Inventors: Li-Xin LIU, Shenzhen (CN); Wei-Kuang LIANG, New Taipei (TW); Hsien-Pin TSOU, New Taipei (TW)

(73) Assignees: HON HAI PRECISION INDUSTRY CO., LTD., New Taipei (TW); HONG FU JIN PRECISION INDUSTRY (ShenZhen) CO., LTD., Shenzhen (CN)

(21) Appl. No.: 13/948,112

(22) Filed: Jul. 22, 2013

(30) Foreign Application Priority Data
Dec. 4, 2012 (CN) 2012105120284

(51) Int. Cl. H05K 5/02; H05K 5/00

(52) U.S. Cl. CPC H05K 5/0221; H05K 5/0004
USPC 312/223.1

(57) ABSTRACT

An electronic device enclosure includes a bottom cover, a bottom frame, and a mounting member. The mounting member is slidable relative to the bottom cover and the bottom frame along a first direction to engage the bottom cover with the bottom frame. The mounting member is slidable relative to the bottom cover and the bottom frame along a second direction to disengage the bottom cover from the bottom frame.

### BACKGROUND

1. Technical Field

The present disclosure relates to electronic device enclosures, and particularly to a notebook enclosure.

2. Description of Related Art

Generally, a notebook includes a bottom frame for securing electronic components, such as a hard disk drive, and a bottom cover covering the bottom frame. In assembly, the bottom frame is engaged in the bottom cover through a number of hooks and then locked to the bottom cover by a number of screws, which is inconvenient and time consuming to assemble. Therefore, there is room for improvement in the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded, isometric view of one embodiment of an electronic device enclosure.

FIG. 2 is similar to FIG. 1, but viewed from a different aspect.

FIG. 3 is an isometric view of a mounting member of the electronic device enclosure of FIG. 2.

FIG. 4 is an assembled, isometric view of the mounting member and a bottom cover of the electronic device enclosure of FIG. 3.

FIG. 5 is an enlarged view of a circled portion V of FIG. 4.

FIG. 6 is an enlarged view of a circled portion VI of FIG. 4.

FIG. 7 is an assembled, isometric view of the electronic device enclosure of FIG. 1.

FIG. 8 is an assembled, isometric view of the electronic device enclosure of FIG. 2.

FIG. 9 is an assembled, isometric view of the mounting member and the bottom cover of the electronic device enclosure of FIG. 1, with a part of the mounting member and the bottom cover cut off.

FIG. 10 is an enlarged view of a circled portion X of FIG. 9.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean “at least one.”

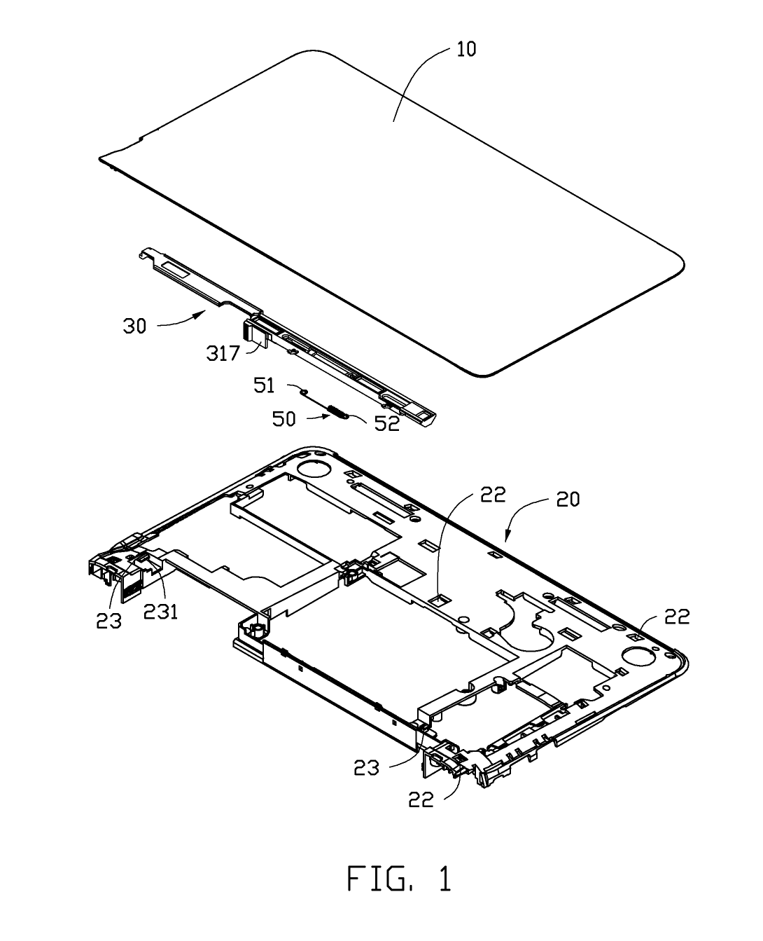

FIG. 1 shows an electronic device enclosure in accordance with an embodiment. The electronic device enclosure includes a bottom cover 10, a bottom frame 20, and a mounting member 30. In one embodiment, the electronic device enclosure is a notebook enclosure.

The bottom cover 10 includes a bottom plate 11 and a plurality of hooks 12 extending from the bottom plate 11. The plurality of hooks 12 is located along edges and toward a center of the bottom plate 11. A plurality of first limiting pieces 111, a plurality of second limiting pieces 112, a plurality of latching portions 113, a mounting post 115, a limiting post 116, and two limiting blocks 117 extend from the bottom plate 11. Each latching portion 113 includes oppositely-facing two resilient pieces 1131. In one embodiment, each first limiting piece 111 and each second limiting piece 112 is substantially perpendicular to the bottom plate 11, and the mounting post 115 and the limiting post 116 is substantially perpendicular to the bottom plate 11.

The bottom frame 20 defines a plurality of latching slots 22 corresponding to the plurality of hooks 12. The bottom frame 20 includes two first latching portions 23. Each first latching portion 23 is substantially “L” shaped and includes a first latching piece 231 extending along a horizontal direction.

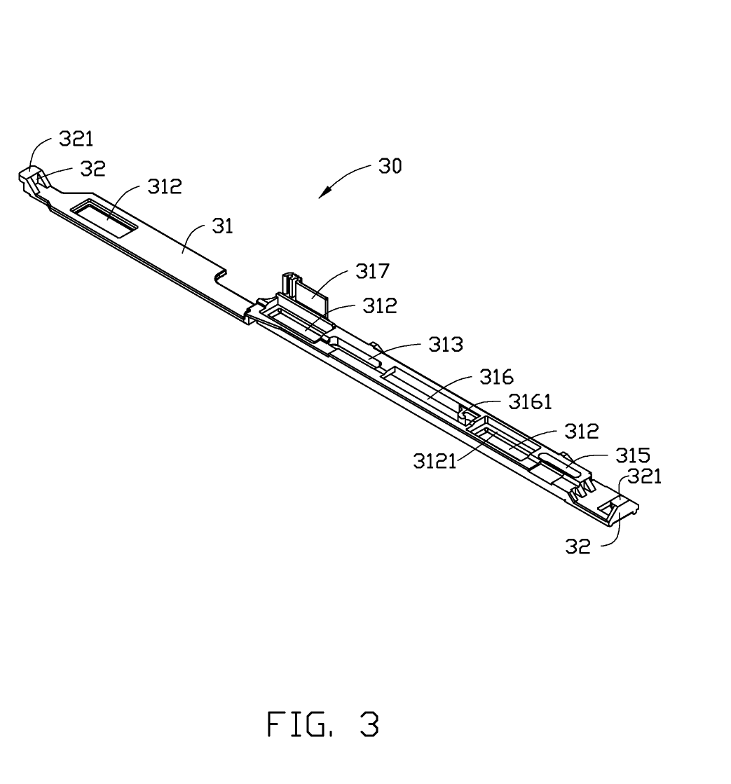

FIG. 3 shows that the mounting member 30 includes a mounting plate 31 and two second latching portions 32, extending from opposite ends of the mounting plates 31. The mounting plate 31 defines a plurality of stepped slots 312 corresponding to the plurality of latching portions 113. Each stepped slot 312 has a latching surface 3121. The mounting plate 31 further defines a mounting slot 313, a limiting slot 315, and a receiving slot 316. The mounting slot 313 is used for receiving the mounting post 115. The limiting slot 315 is used for receiving the limiting post 116. A bent portion 3161 extends from a sidewall of the receiving slot 316 away from the mounting slot 313. An extending direction of the mounting slot 313 is the same as that of the limiting slot 315 and the receiving slot 316. An operation piece 317 extends from a side edge of the mounting plate 31. The operation piece 317 is used to allow the mounting member 30 to slide. Each second latching portion 32 includes a second latching piece 321 extending horizontally. A height of the resilient piece 1131 is smaller than a depth of the stepped slot 312, to prevent the two resilient pieces 1131 from extending out of the stepped slot 312.

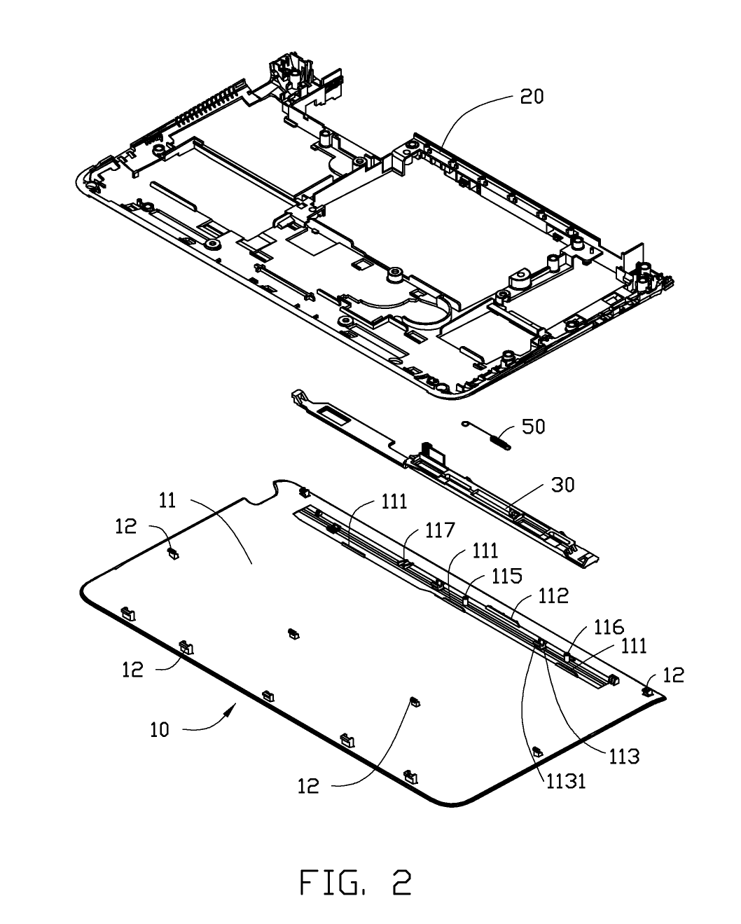

Referring to FIG. 1 and FIG. 2, the electronic device enclosure further includes a resilient member 50. The resilient member 50 includes a first ear 51 and a second ear 52. In one embodiment, the resilient member 50 is a stretch spring.

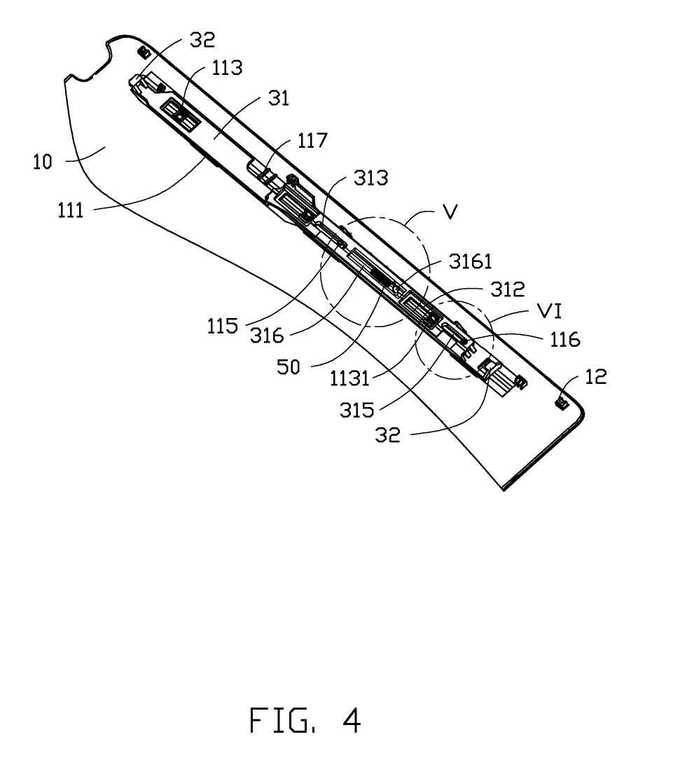

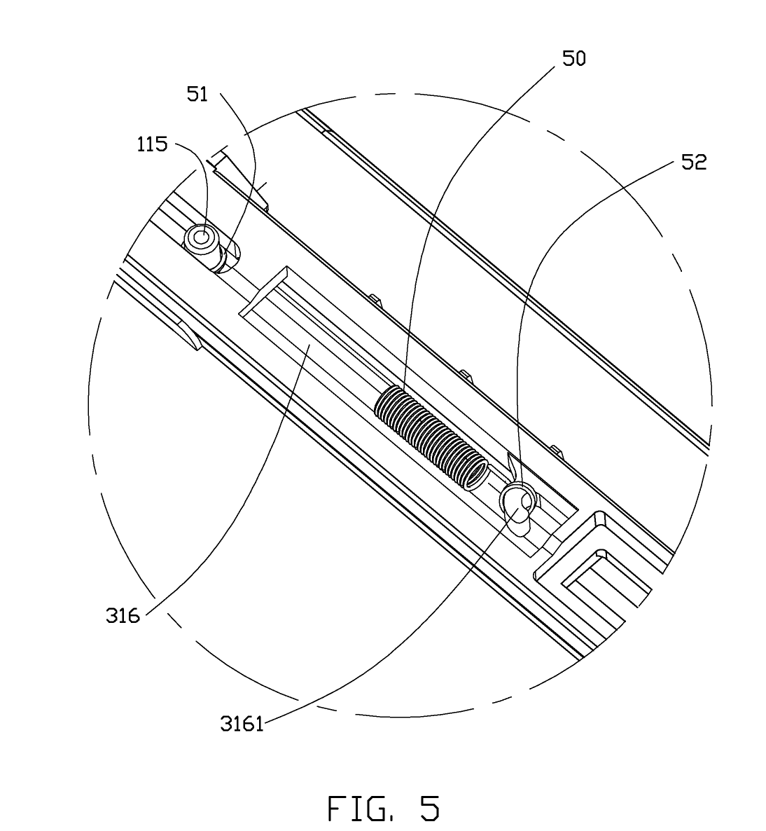

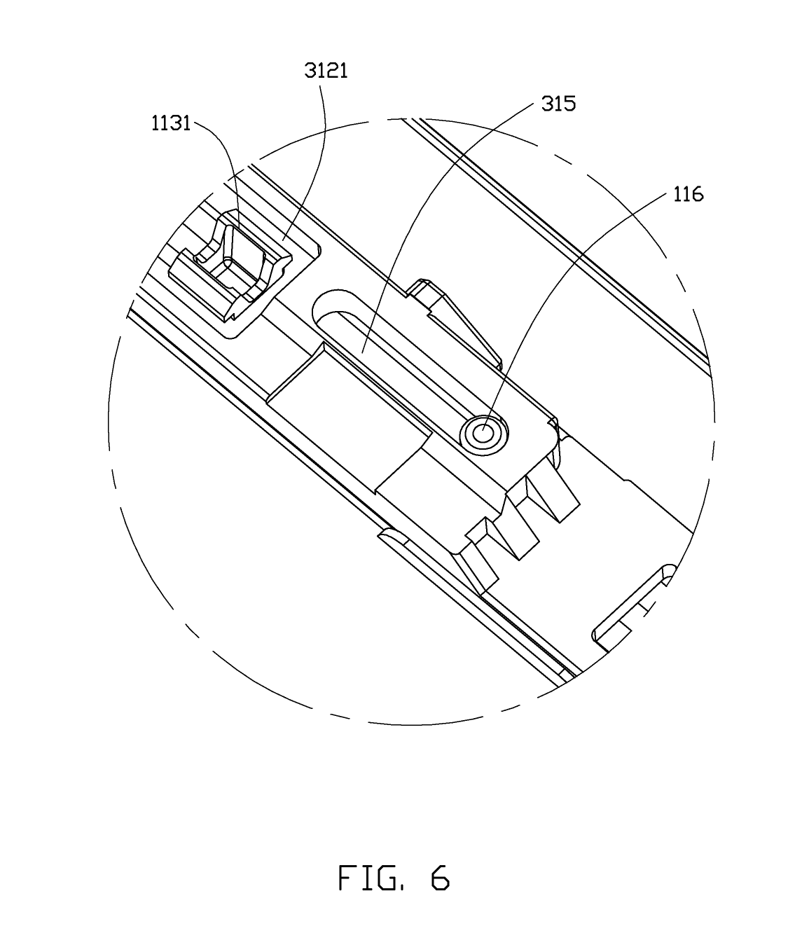

FIGS. 4-6 show that in assembly, the mounting member 30 is adjacent to the bottom cover 10, the mounting post 115 is aligned with the mounting slot 313, the limiting post 116 is aligned with the limiting slot 315, and each latching portion 113 is aligned with one of the plurality of stepped slots 312. The first ear 51 is secured to the mounting post 115, while the second ear 52 is secured to the bent portion 3161, such that the resilient member 50 is received by the receiving slot 316. The mounting member 30 is pressed towards the bottom cover 10, causing the two resilient pieces 1131 to elastically deform towards each other and then insert into the stepped slot 312. The two resilient pieces 1131 rebound to engage with the latching surface 3121 when the mounting member 30 abuts the bottom cover 10. In this position, the resilient member 50 is stretched. The first limiting pieces 111 are located on a first side of the mounting member 30, while the second limiting pieces 112 and the limiting blocks 117 are located on a second side of the mounting member 30 to prevent the mounting member 30 from moving along a first direction. The latching portions 113 prevent the mounting member 30 from moving along a second direction. The first direction is substantially parallel to the bottom plate 11. The second direction is substantially perpendicular to the first direction. The mounting member 30 is slidable along a third direction, which is substantially parallel to the bottom plate 11 and perpendicular to the first direction.

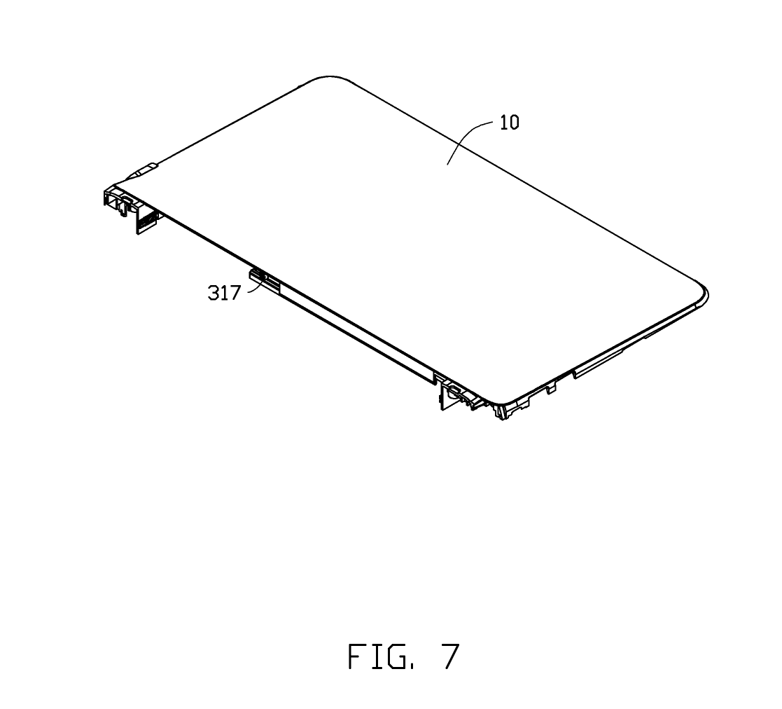

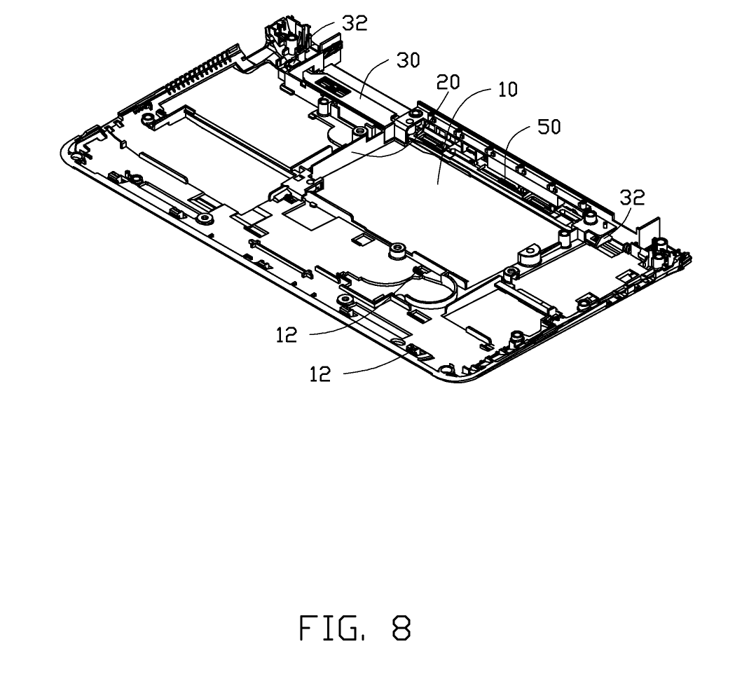

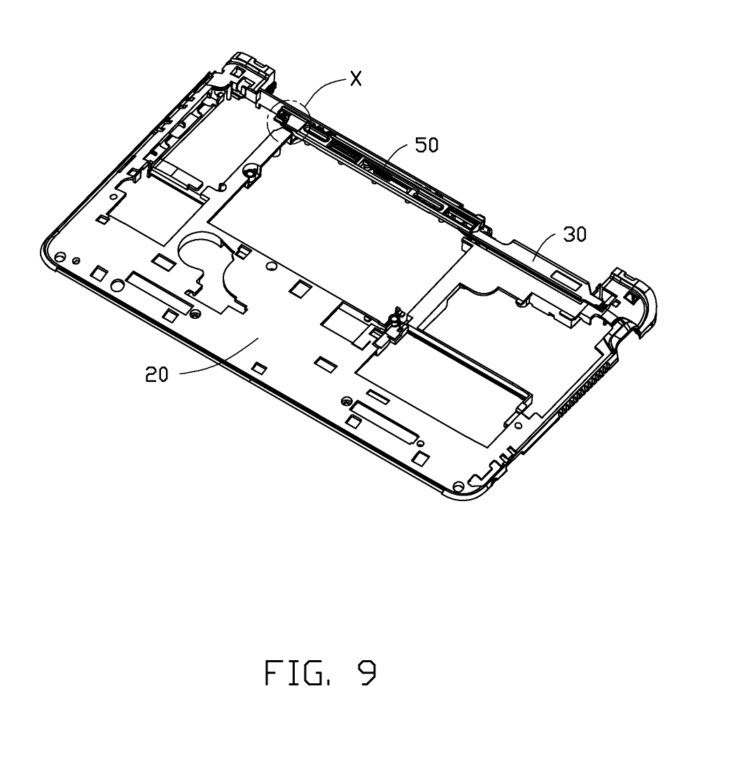

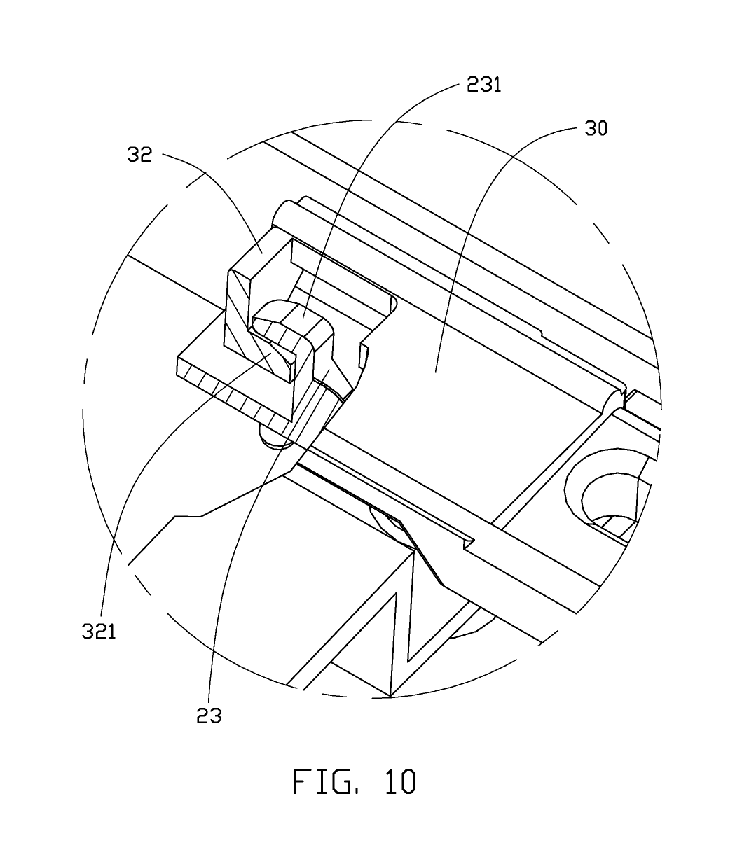

FIGS. 7-10 show that in assembly of the bottom cover to the bottom frame 20, the bottom cover 10 is moved towards the bottom frame 20, and the mounting member 30 faces the bottom frame 20. Each hook 12 is aligned with one of the latching slots 22, and each second latching portion 32 is aligned with one of the first latching portions 23. The bottom cover 10 is pressed towards the bottom frame 20, so that the second latching piece 321 is pressed by the first latching piece 231, causing the mounting member 30 to slide relative to the bottom cover 10 and the bottom frame 20 along the third direction. The resilient member 50 is further elastically deformed. The second latching piece 321 is slid over the first latching piece 231 to abut the bottom frame 20. In this position, the resilient member 50 rebounds to slide the mounting member 30 along a fourth direction, which is opposite to the third direction, until the second latching piece 321 is engaged with the first latching piece 231. The first latching portion 23 blocks the second latching portion 32 from sliding along the fourth direction. Each hook 12 is engaged in one of plurality of latching slots 22. Thus, the mounting member 30 secures the bottom cover 10 to the bottom frame 20.

In disassembly, the operation piece 317 is pulled along the third direction to slide the mounting member 30 along the third direction relative to the bottom cover 10 and the bottom frame 20, causing the second latching piece 321 to disengage from the first latching piece 231. Thus, the bottom cover 10 is easily removed from the bottom frame 20.

It is to be understood, however, that even though numerous characteristics and advantages have been set forth in the foregoing description of embodiments, together with details of the structures and functions of the embodiments, the disclosure is illustrative only and changes may be made in detail, especially in the matters of shape, size, and the arrangement of parts within the principles of the disclosure, to the full extent indicated by the broad general meaning of the terms in which the appended claims are expressed.

What is claimed is:

1. An electronic device enclosure comprising:
a bottom cover defining a latching slot and comprising a first latching portion;
a bottom frame comprising a hook engaged in the latching slot; and
a mounting member slidably mounted on the bottom frame and comprising a second latching portion;
wherein the mounting member is slidable relative to the bottom cover and the bottom frame along a first direction or a second direction; when the mounting member is slid along the first direction, the second latching portion is engaged with the second latching portion to secure the bottom frame to the bottom cover; and when the mounting member is slid along the second direction, the second latching portion is disengaged from the second latching portion.

2. The electronic device enclosure of claim 1, wherein the bottom frame further comprises a latching portion comprising two resilient pieces substantially parallel to each other; the mounting member defines a stepped slot, which has a latching surface; and the latching portion is received in the stepped slot, and the two resilient pieces are engaged with the latching surface.

3. The electronic device enclosure of claim 1, wherein the bottom frame comprises a bottom plate, a first limiting piece, and a second limiting piece extending from the bottom plate; and the mounting member is located between the first limiting piece and the second limiting piece.

4. The electronic device enclosure of claim 1, further comprising a resilient member, wherein the resilient member comprises a first end and a second end opposite to the first end, the first end is secured to the bottom frame, and the second end is secured to the mounting member.

5. The electronic device enclosure of claim 4, wherein the bottom frame further comprises a mounting post, and the mounting member defines a receiving slot and comprising a bent portion in the receiving slot; the resilient member is received in the receiving slot; and the first end is secured to the mounting post, and the second end is secured to the bent portion.

6. The electronic device enclosure of claim 5, wherein the bent portion extends towards the mounting post.

7. The electronic device enclosure of claim 5, wherein the mounting member further defines a mounting slot, and the mounting post is received in the mounting slot and slidable relative to the mounting member in the mounting slot.

8. The electronic device enclosure of claim 1, wherein the mounting member further comprises a limiting slot, the bottom frame further comprises a limiting post, and the limiting post is received in the limiting slot and slidable relative to the mounting member in the limiting slot.

9. The electronic device enclosure of claim 1, wherein the mounting member further comprises an operation portion, and the operation portion is operable to slide the mounting member.

10. The electronic device enclosure of claim 1, wherein each of the first latching portion and the second latching portion is “L” shaped.

11. An electronic device enclosure comprising:
a bottom cover defining a latching slot and comprising a first latching portion;
a bottom frame comprising a hook engaged in the latching slot;
a mounting member slidably mounted on the bottom frame and comprising a second latching portion; and
a resilient member comprising a first end and a second end opposite to the first end, the first end is secured to the bottom frame, and the second end is secured to the mounting member;
wherein the mounting member is slidable relative to the bottom cover and the bottom frame along a first direction or a second direction; when the mounting member is slid along the first direction, the second latching portion is engaged with the second latching portion to secure the bottom frame to the bottom cover; and when the mounting member is slid along the second direction, the second latching portion is disengaged from the second latching portion.

12. The electronic device enclosure of claim 11, wherein the bottom frame further comprises a latching portion comprising two resilient pieces substantially parallel to each other; the mounting member defines a stepped slot, which has a latching surface; and the latching portion is received in the stepped slot, and the two resilient pieces are engaged with the latching surface.

13. The electronic device enclosure of claim 11, wherein the bottom frame comprises a bottom plate, a first limiting piece, and a second limiting piece extending from the bottom plate; and the mounting member is located between the first limiting piece and the second limiting piece.

14. The electronic device enclosure of claim 11, wherein the bottom frame further comprises a mounting post, and the mounting member defines a receiving slot and comprising a bent portion in the receiving slot; the resilient member is received in the receiving slot; and the first end is secured to the mounting post, and the second end is secured to the bent portion.

15. The electronic device enclosure of claim 14, wherein the bent portion extends towards the mounting post.

16. The electronic device enclosure of claim 14, wherein the mounting member further defines a mounting slot, and the mounting post is received in the mounting slot and slidable relative to the mounting member in the mounting slot.

17. The electronic device enclosure of claim 11, wherein the mounting member further comprises a limiting slot, the bottom frame further comprises a limiting post, and the limiting post is received in the limiting slot and slidable relative to the mounting member in the limiting slot.

18. The electronic device enclosure of claim 11, wherein the mounting member further comprises an operation portion, and the operation portion is operable to slide the mounting member.

19. The electronic device enclosure of claim 11, wherein each of the first latching portion and the second latching portion is “L” shaped.
